(19) United States
(12) Patent Application Publication
(10) Pub. No.: US 2025/0149334 A1
(43) Pub. Date: May 8, 2025

(54) LATTICE POLARITY CONTROL IN III-NITRIDE SEMICONDUCTOR HETEROSTRUCTURES

(71) Applicant: The Regents of the University of Michigan, Ann Arbor, MI (US)

(72) Inventors: Ping Wang, Ann Arbor, MI (US); Ding Wang, Ann Arbor, MI (US); Zetian Mi, Ann Arbor, MI (US)

(21) Appl. No.: 18/837,812

(22) PCT Filed: Feb. 13, 2023
(86) PCT No.: PCT/US2023/012913

§ 371 Date: Aug. 12, 2024

Related U.S. Application Data
(60) Provisional application No. 63/309,495, filed on Feb. 11, 2022.

(51) Int. Cl. H01L 21/02; C30B 25/18; C30B 29/40; C30B 29/68; H10D 30/47; H10D 62/85

(52) U.S. Cl. CPC H01L 21/02458; C30B 25/183; C30B 29/403; C30B 29/406; C30B 29/68; H01L 21/02381; H01L 21/0254; H01L 21/0262; H10D 30/475; H10D 62/8503

(57) ABSTRACT

A method of fabricating a heterostructure includes growing epitaxially, in a growth chamber, a first semiconductor layer of the heterostructure, the first semiconductor layer including a first III-nitride semiconductor material, the first semiconductor layer being supported by a substrate, after growing the first semiconductor layer, growing epitaxially, in the growth chamber, a second semiconductor layer of the heterostructure such that the second semiconductor layer is supported by the first semiconductor layer, the second semiconductor layer including a second III-nitride semiconductor material, and between growing the first semiconductor layer and growing the second semiconductor layer, controlling an extent to which a eutectic layer disposed on the first semiconductor layer is consumed to control a lattice polarity of the second semiconductor layer

### CROSS-REFERENCE TO RELATED APPLICATION

This application claims the benefit of U.S. provisional application entitled “Lattice Polarity Control in III-Nitride Semiconductor Heterostructures,” filed Feb. 11, 2022, and assigned Ser. No. 63/309,495, the entire disclosure of which is hereby expressly incorporated by reference.

### STATEMENT REGARDING FEDERALLY SPONSORED RESEARCH OR DEVELOPMENT

This invention was made with government support under Contract No. N00014-19-1-2225 awarded by the Naval Research Office. The government has certain rights in the invention.

### BACKGROUND OF THE DISCLOSURE

### Field of the Disclosure

The disclosure relates generally to III-nitride semiconductor heterostructures.

### Brief Description of Related Technology

III-nitride semiconductors as well as their new members, such as hBN and ScAlN, have attracted tremendous interest due to a broad range of applications, including solid-state lighting, power electronics, quantum information, renewable energy, and environmental health. However, due to the lack of economical native substrates, III-nitride semiconductors were mainly hetero-epitaxially grown on foreign substrates, such as sapphire (Al₂O₃), silicon (Si), and silicon carbide (SiC), as well as some hybrid substrates decorated with two-dimensional materials. Si has long been a desired substrate thanks to the very low cost, large area, and opportunity for seamless chip-scale integration. In this regard, significant progress has been made in addressing the challenges related to the large lattice mismatch and thermal expansion coefficient mismatch presented by the epitaxy of III-nitride semiconductors on Si.

Due to the rich physics introduced by polarization, such as interface charge reconstruction and space charge transfer, lattice polarity controlled epitaxy of nitrides on Si has also attracted tremendous interest. To engineer the lattice polarity of III-nitride semiconductors on nonpolar Si substrates, various approaches have been proposed and studied, including (i) substrate pretreatments, (ii) modulation of growth conditions, and (iii) insert layer engineering. Nevertheless, the nonpolar surface of Si substrates as well as the relatively low formation temperature of IIIA-Si eutectic materials make the lattice polarity control of nitrides on Si substrates challenging. Lattice polarity inverted domains (IDs) have been commonly observed in GaN grown on Si, such as planar/vertical inverted domain boundaries (IDBs) in epilayers and core/shell structures with opposite lattice polarity in nanowires. Such IDs and IDBs severely limit the device applications for III-nitride semiconductors.

### SUMMARY OF THE DISCLOSURE

In accordance with one aspect of the disclosure, a method of fabricating a heterostructure includes growing epitaxially, in a growth chamber, a first semiconductor layer of the heterostructure, the first semiconductor layer including a first III-nitride semiconductor material, the first semiconductor layer being supported by a substrate, after growing the first semiconductor layer, growing epitaxially, in the growth chamber, a second semiconductor layer of the heterostructure such that the second semiconductor layer is supported by the first semiconductor layer, the second semiconductor layer including a second III-nitride semiconductor material, and between growing the first semiconductor layer and growing the second semiconductor layer, controlling an extent to which a eutectic layer disposed on the first semiconductor layer is consumed to control a lattice polarity of the second semiconductor layer.

In accordance with another aspect of the disclosure, a method of fabricating a heterostructure includes growing epitaxially a first semiconductor layer of the heterostructure, the first semiconductor layer including a first III-nitride semiconductor material, the first semiconductor layer being supported by a substrate, growing epitaxially a second semiconductor layer of the heterostructure such that the second semiconductor layer is supported by the first semiconductor layer, the second semiconductor layer including a second III-nitride semiconductor material, and between growing the first semiconductor layer and growing the second semiconductor layer, annealing the first semiconductor layer in an active nitrogen-free environment to evaporate Group IIIA metal atoms of a eutectic layer disposed on the first semiconductor layer to maintain a lattice polarity of the first semiconductor layer in the second semiconductor layer.

In accordance with another aspect of the disclosure, a method of fabricating a heterostructure includes growing epitaxially a first semiconductor layer of the heterostructure, the first semiconductor layer including a first III-nitride semiconductor material, the first semiconductor layer being supported by a substrate, growing epitaxially a second semiconductor layer of the heterostructure such that the second semiconductor layer is supported by the first semiconductor layer, the second semiconductor layer including a second III-nitride semiconductor material, and between growing the first semiconductor layer and growing the second semiconductor layer, exposing an incidental eutectic coating on the first semiconductor layer to an active nitrogen environment, the incidental eutectic coating including silicon and a cation species of the first III-nitride semiconductor material. Growing the second semiconductor layer is implemented in a nitrogen-rich environment such that exposing the incidental eutectic coating forms an intermediate layer at an interface between the first and second semiconductor layers from the incidental eutectic coating such that a lattice polarity of the second semiconductor layer is toggled relative to the first semiconductor layer.

In accordance with yet another aspect of the disclosure, a device includes a substrate, and a semiconductor heterostructure supported by the substrate. The semiconductor heterostructure includes a first semiconductor layer supported by the substrate and including a first III-nitride semiconductor material, and a second semiconductor layer supported by, and in contact with, the first semiconductor layer and including a second III-nitride semiconductor material differing from the first III-nitride semiconductor material. The first and second semiconductor layers are nitrogen polar.

In accordance with still yet another aspect of the disclosure, a device includes a substrate, and a semiconductor heterostructure supported by the substrate. The semiconductor heterostructure includes a plurality of III-nitride semiconductor layers supported by the substrate, and the semiconductor heterostructure further includes a plurality of intermediate layers, each intermediate layer of the plurality of intermediate layers being disposed between a respective pair of adjacent III-nitride semiconductor layers of the plurality of III-nitride semiconductor layers. Each intermediate layer of the plurality of intermediate layers includes silicon. The adjacent III-nitride semiconductor layers of each pair of adjacent III-nitride semiconductor layers of the plurality of III-nitride semiconductor layers have different lattice polarities.

In accordance with still yet another aspect of the disclosure, a device includes a substrate, and a semiconductor heterostructure supported by the substrate. The semiconductor heterostructure includes a plurality of III-nitride semiconductor layers supported by the substrate, and a first III-nitride semiconductor layer of the plurality of Ill-nitride semiconductor layers includes a first section having a first lattice polarity, and a second section laterally adjacent to the first section and having a second lattice polarity differing from the first lattice polarity.

In connection with any one of the aforementioned aspects, the devices and/or methods described herein may alternatively or additionally include or involve any combination of one or more of the following aspects or features. Controlling the extent to which the eutectic layer is consumed controls the lattice polarity of the second semiconductor layer based on whether an intermediate layer is formed from the eutectic material between the first and second semiconductor layers. Presence of the intermediate layer between the first and second semiconductor layers toggles the lattice polarity of the second semiconductor layer from a lattice polarity of the first semiconductor layer. Absence of the intermediate layer between the first and second semiconductor layers allows a lattice polarity of the first semiconductor layer to persist in the second semiconductor layer. The eutectic layer includes silicon and a Group III cation species of the first III-nitride semiconductor material. Consumption of the eutectic layer forms an intermediate layer between the first and second semiconductor layers. The intermediate layer is doped with silicon. The intermediate layer establishes an interface between the first and second semiconductor layers. Controlling the extent to which the eutectic layer is consumed includes suppressing consumption of the eutectic layer. Suppressing the consumption includes annealing the first semiconductor layer in an active-nitrogen-free environment. Annealing the first semiconductor layer is implemented without flux of a Group III cation species. The first and second semiconductor layers are nitrogen polar. Controlling the extent to which the eutectic layer is consumed includes facilitating consumption of the eutectic layer. Facilitating consumption of the eutectic layer includes exposing the eutectic layer to an active nitrogen environment, and growing the second semiconductor layer in a nitrogen-rich environment. One of the first and second semiconductor layers is nitrogen polar, and the other of the first and second semiconductor layers is metal polar. The method further includes forming the eutectic layer on a surface of the substrate before growing the first semiconductor layer. The method further includes forming a further eutectic layer on a surface of the second semiconductor layer, growing epitaxially, in the growth chamber, a Ill-nitride semiconductor layer of the heterostructure such that the III-nitride semiconductor layer is supported by the second semiconductor layer, and controlling an extent to which the further eutectic layer disposed on the second semiconductor layer is consumed to control a lattice polarity of the III-nitride semiconductor layer supported by the second semiconductor layer. The first semiconductor material is aluminum nitride (AlN). The second semiconductor material is gallium nitride (GaN). The substrate includes silicon such that the eutectic layer includes silicon. Growing epitaxially the first semiconductor layer is implemented in a metal-rich environment. Growing epitaxially the second semiconductor layer is implemented in a metal-rich environment. Growing the second semiconductor layer is implemented without removal of the substrate from the growth chamber after growth of the first semiconductor layer. The first semiconductor material is aluminum nitride (AlN), the second semiconductor material is gallium nitride (GaN), and the substrate includes silicon. The first semiconductor layer is configured as a buffer layer of a transistor device. The second semiconductor layer is configured as a channel layer of the transistor device. The semiconductor heterostructure further includes a barrier layer supported by the buffer layer and including a compound semiconductor material, wherein the barrier layer is nitrogen polar. Each intermediate layer of the plurality of intermediate layers includes a doped crystalline material, and the doped crystalline layer is doped with silicon. Each intermediate layer of the plurality of intermediate layers includes AISIN. Each semiconductor layer the plurality of semiconductor layers is composed of a same III-nitride semiconductor material. At least two of the plurality of semiconductor layers are composed of different III-nitride semiconductor materials. The plurality of III-nitride semiconductor layers includes a second III-nitride semiconductor layer supported by the first III-nitride semiconductor layer. The first and second III-nitride semiconductor layers have different compositions. The second III-nitride semiconductor layer includes first and second sections supported by the first and second sections of the first III-nitride semiconductor layer, respectively, and having the first and second lattice polarities, respectively. The first III-nitride semiconductor layer includes a set of N-polar sections and a set of metal-polar sections. The set of N-polar sections and the set of metal-polar sections are disposed in a periodic, alternating arrangement.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts reflection high energy electron diffraction (RHEED) patterns, atomic force microscope (AFM) images, and scanning electron microscope (SEM) images (before and after wet chemical etching) of example AlN layers grown on Si(111) substrates using different elemental flux (III/V) ratios.

FIG. 2 depicts annular bright field scanning transmission electron microscope (ABF-STEM) images of example AlN heterostructures grown on silicon substrates with varied elemental flux ratios, along with corresponding element maps, element K-edge signal profiles, high-resolution high-angle annular dark field scanning transmission electron microscope (HAADF-STEM) images.

FIG. 3 depicts schematic views of a number of heterostructures (e.g., AlN/Si heterostructures) with lattice polarity controlled in accordance with a number of examples.

FIG. 4 depicts RHEED patterns, AFM images, and SEM images of GaN/AlN heterostructures in accordance with two examples.

FIG. 5 depicts high-resolution HAADF STEM and ABF-STEM images of N-polar GaN/AlN heterostructures on silicon substrates in accordance with one example.

FIG. 6 is a flow diagram of a method of fabricating a heterostructure with lattice polarity control in accordance with one example.

FIG. 7 depicts schematic views of transistor devices having a heterostructure in accordance with two examples.

FIG. 8 depicts a schematic view of a transistor device having a heterostructure with alternating lattice polarity in accordance with another example.

FIG. 9 depicts schematic views of the fabrication of a GaN/AlN/Si heterostructure with laterally controlled lattice polarity in accordance with one example.

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Methods of fabricating transistor and other devices with III-nitride heterostructures in which lattice polarity is controlled are described. Lattice polarity may be maintained, modulated, or otherwise controlled by controlling the extent to which a eutectic layer present during the growth of the heterostructures is consumed. Examples of transistor and other devices having the resulting heterostructures are also described. The lattice polarity control of the methods used to fabricate the heterostructures allows the subsequently grown layers of the heterostructures to retain the lattice polarity of the previously grown layer. The lattice polarity control may conversely be used to toggle or otherwise modulate the lattice polarity of adjacent layers of the heterostructure. To realize these different types of heterostructures, one aspect of the disclosed methods is directed to a technique for interfacial modulated lattice polarity controlled epitaxy of III-nitride heterostructures. Such heterostructures may be formed on, or otherwise include, silicon substrates (e.g., Si(111)) or other substrates, such as sapphire and SiC.

The disclosed methods and devices make use of one or more eutectic coatings or other layers present during the epitaxial growth of III-nitride heterostructures. The disclosed methods are configured to control the extent to which the eutectic coating or other layer is consumed during the epitaxial growth process. The eutectic layer(s) may be incidentally or intentionally formed. In the former cases, the eutectic layer is incidentally present as a result of growth of the heterostructure on a silicon substrate. In the latter cases, one or more eutectic layers may be formed on a substrate (e.g., a non-silicon substrate) or on a semiconductor layer of the heterostructure via the deposition of Si atoms.

AlN buffer layers have been employed to avoid the “metal-back etching” behavior of GaN on Si. However, little attention has been paid to the unavoidable formation of an Al—Si eutectic layer, which can occur at about 577° C., well below the growth temperature (e.g., about 700-1200° C.) commonly used for AlN epitaxy. As described herein, with sufficient Al supply, e.g., Al-rich conditions, a liquid phase Al—Si eutectic layer tends to float on top of the AlN surface during the epitaxy of AlN.

However, with insufficient Al-supply, e.g., N-rich conditions, both Al and Si atoms in the Al—Si eutectic layer are incorporated at the growth front, thereby forming an unintentionally Si-doped AlN interlayer. At the commonly used AlN growth temperature (>700° C.), the concentration of Si in Al—Si eutectic can be up to 20%. As a consequence, the incorporation of Si atoms results in the formation of a heavily Si-doped AlSiN interlayer, severely distorting the atomic stacking sequence for wurtzite AlN and leading to the loss of lattice polarity hereditability. From another perspective, such a heavily Si-doped AlSiN interlayer may also provide an additional dimension to modulate the lattice polarity. The underlying mechanism and effect of the Al—Si eutectic layer, as well as the AISIN interlayer, on the lattice polarity of III-nitride layers grown on Si are thus addressed herein.

The disclosed methods and devices may involve an interfacial modulated lattice polarity-controlled epitaxy (IMLPCE) strategy to precisely control the lattice polarity of III-nitrides on Si(111) substrates by exploiting the formation of the interlayer (e.g., an AISIN interlayer) from the eutectic layer. In this approach, the epitaxy of N-polar and Al-polar AlN on Si(111) substrates can be achieved by suppressing and promoting the formation of the AlSiN interlayer from the Al—Si eutectic layer, respectively.

The disclosed methods may include an active nitrogen-free in situ annealing procedure. The nitrogen-free annealing may be used to mitigate the impact of the AISIN interlayer on subsequent III-nitride (e.g., GaN) growth, which can eliminate the inverted domain formation commonly seen in N-polar GaN grown on Si substrates. With the annealing procedure, the disclosed methods may provide for the controlled epitaxy of GaN/AlN and other III-nitride heterostructures on Si with controlled nitrogen lattice polarity (N-polar heterostructures), atomically sharp heterointerfaces, and the absence of lattice polarity inversions (e.g., inverted domains).

Described herein are examples of direct epitaxy of wurtzite III-nitrides on nonpolar silicon (Si), the two most produced semiconductor materials. Such direct epitaxy is useful in connection with a broad range of applications in electronics, optoelectronics, quantum photonics, and renewable energy. The disclosed methods address the challenges of achieving III-nitride heterostructures on Si with controlled lattice polarity. The challenges of III-nitride semiconductors on, e.g., Si(111), can be fundamentally addressed through a unique interfacial modulated lattice polarity-controlled epitaxy (IMLPCE). In this IMLPCE strategy, the lattice polarity of aluminum nitride (AlN) grown on Si(111) is primarily determined by the AlSiN interlayer: N and Al-polar AlN can be achieved by suppressing and promoting the AlSiN interlayer formation, respectively. Furthermore, the disclosed methods may include an active-nitrogen-free in situ annealing process to mitigate the formation of a nonpolar AlSiN layer at the GaN/AlN interface. Such mitigation may eliminate the inverted domain formation commonly seen in N-polar GaN on AlN/Si. In these and other ways, the disclosed methods and devices address the challenges for the lattice polarity-controlled epitaxy of III-nitride semiconductors on Si, thereby enabling seamless integration of the III-nitride semiconductors with Si-based device technologies.

Although described in connection with HEMT devices, the disclosed methods and devices may be applied to a wide variety of electronic and other devices. For instance, the disclosed devices may be non-electronic devices, such as optoelectronic, photonic, acoustic, and piezoelectric devices.

Although described in connection with examples having a AlN layer and/or a GaN layer, the disclosed methods and devices are also useful in connection with other III-nitride materials. For instance, III-nitride semiconductor materials in addition or alternative to AlN and GaN, such as InN and ScAlN, and alloys thereof, may be used.

The configuration, construction, fabrication, and other characteristics of the heterostructures may also vary from the examples described. For instance, the heterostructures may include any number of epitaxially grown layers.

The heterostructures of the disclosed devices may include any number of other alloys of III-nitride materials, including, for instance, ScAlN layers (e.g., single-crystalline ScAlN). In some cases, such layers exhibit robust ferroelectric switching. Further details regarding such layers are set forth in U.S. Application Ser. No. 63/185,669, entitled “Epitaxial Nitride Ferroelectronics” and filed May 7, 2021, and P. Wang, et al., “Fully epitaxial ferroelectric ScAlN grown by molecular beam epitaxy,” Applied Physics Letters 118, 223504 (2021), the entire disclosures of which are hereby incorporated by reference.

Although described in connection with MBE growth procedures, additional or alternative non-sputtered epitaxial growth procedures may be used. For instance, metal-organic chemical vapor deposition (MOCVD) and hydride vapor phase epitaxy (HVPE) growth procedures may be used. Still other procedures may be used, including, for instance, pulsed laser deposition procedures.

To demonstrate this IMLPCE strategy of the disclosed methods, four AlN samples were grown by MBE on Si(111) with varying growth conditions, as listed in Table 1. The varying growth conditions were used to evaluate the effect of surface pretreatment and growth temperature on lattice polarity. It was found that the lattice polarity of AlN is insensitive to both pretreatment and growth temperature, which is in contrast to some previous reports.

TABLE 1
Growth parameters of AlN on Si(111), including substrate temperature
(T_{sub}), III/V ratio, AlN growth duration (t_{AlN}), and the surface
RMS roughness (R_{q}) and lattice polarity.

| | | | t_{AlN} | | Lattice- |
|---|---|---|---|---|---|
| Sample | T_{sub} | III/V | (min) | R_{q} (nm) | polarity |
| S1 | 800 | 1.2 | 30 | 0.44 | N-polar |
| S2 | 800 | 0.8 | 30 | 1.64 | Al-polar |
| S3 | 800 | 1.2 | 15 | 1.59 | Al-polar |
| | 800 | 0.8 | 15 | | |
| S4 | 800 | 0.8 | 15 | 0.82 | Al-polar |
| | 800 | 1.2 | 15 | | |

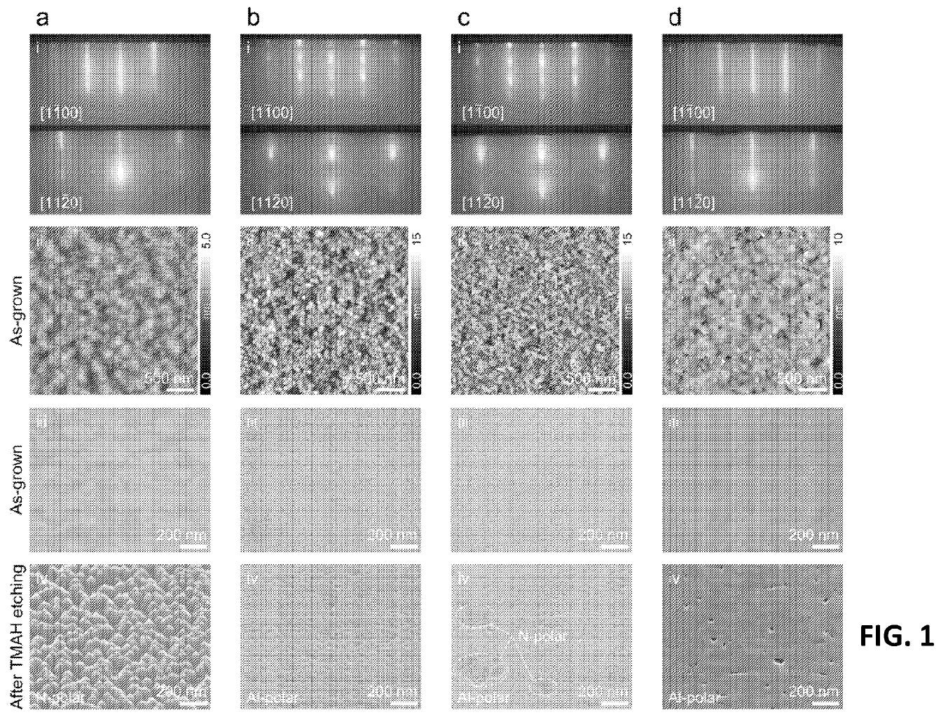

FIG. 1 depicts example AlN layers grown on Si(111) substrates using different elemental flux (III/V) ratios: in part (a), sufficient Al supply (III/V=1.2, sample S1); in part (b), insufficient Al supply (III/V=0.8, sample S2); in part (c), changed from sufficient to insufficient Al supply (III/V=1.2 to 0.8, sample S3); and in part (d), changed from insufficient to sufficient Al supply (III/V=0.8 to 1.2, sample S4). Panels i, ii, iii, and iv of each part of FIG. 1 are the corresponding final RHEED patterns, AFM images, and SEM images (before and after wet chemical etching) of the AlN layers. The RMS roughness measurements for (a) (ii)-(d) (ii) were 0.44, 1.64, 1.59, and 0.82 nm, respectively. The yellow dashed circles in part (c) (iv) indicate the pyramidal structures after wet chemical etching, suggesting the existence of an N-polar domain.

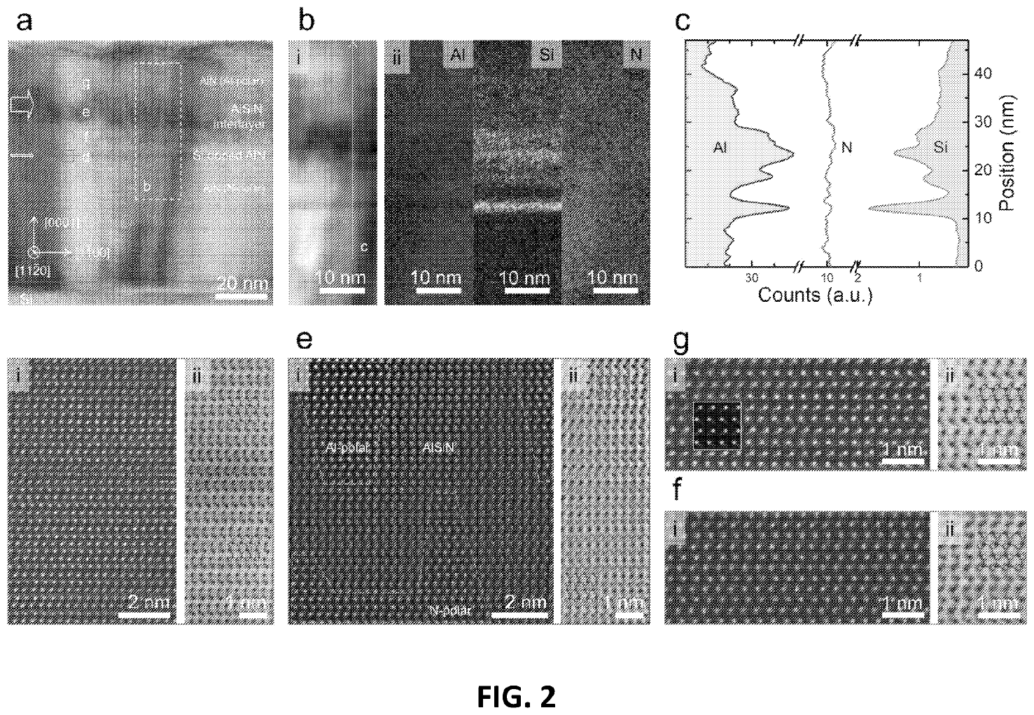

To avoid the consumption of the Al—Si eutectic at the growth front, sample S1 was grown with sufficient Al-supply (Al-rich). Shown in part (a) (i) of FIG. 1, streaky RHEED patterns were observed, indicating a smooth surface for AlN. Part (a) (ii) of FIG. 1 shows the AFM image with a corresponding root mean square (RMS) roughness (Ra) of about 0.44 nm. The hexagonal pyramidal morphology after wet chemical etching unambiguously confirms that sample S1 is N-polar AlN (see part (a) (iii, iv) of FIG. 1). To ensure the complete consumption of the Al—Si eutectic layer at the nucleation stage, sample S2 was grown with insufficient Al supply (N-rich). The N-rich conditions result in spotty RHEED patterns (see part (b) (i) of FIG. 2), as well as a granular surface (RMS=1.64 nm, part (b) (ii) of FIG. 2). Interestingly, the typical hexagonal pyramidal morphology for N-polar nitrides is absent in sample S2 after wet chemical etching (see part (b) (iii, iv) of FIG. 1). This indicates that the AlN grown with insufficient Al supply possesses an Al-polar lattice.

To further explore the effect of varying elemental flux ratio on lattice polarity, the growth conditions for sample S3 were switched from Al-rich to N-rich at the last half of the growth, while growth conditions inverse to sample S3 were applied for sample S4. Due to the final N-rich growth, sample S3 also showed spotty RHEED patterns (see part (c) (i) of FIG. 1) and granular surface (RMS=1.59 nm, part (c) (ii) of FIG. 1). However, the hexagonal pyramidal structures were only observed occasionally in some regions after wet chemical etching (part (c) (iii, iv) of FIG. 1). This indicates that the lattice polarity of sample S3 was dominated by Al-polar regions, i.e., the initial N-polar lattice was inverted to an Al-polar lattice following the change of elemental flux ratio from Al-rich to N-rich. In sample S4, the spotty RHEED patterns were recovered to streaky ones (see part (d) (i) of FIG. 1) by applying Al-rich conditions, resulting in a smooth surface as well (RMS=0.82 nm, part (d) (ii) of FIG. 1). Unexpectedly, as shown in part (d) (iii, iv) of FIG. 1, the lattice polarity remained Al-polar, which did not change with the switching of growth conditions from N-rich to Al-rich.

These experimental results suggest that the lattice polarity of AlN grown on Si(111) can be affected but not solely determined by varying elemental flux ratios. To elucidate the underlying mechanism, the microstructure of sample S3, in which the lattice polarity inversion happened, was analyzed in detail using high-angle annular dark-field (HAADF) and annular bright field (ABF) STEM.

FIG. 2 presents the following analysis of the lattice polarity inversion of an example AlN heterostructure grown on a Si(111) substrate: in part (a), a cross-sectional ABF-STEM image of the AlN/Si heterostructures grown with varied elemental flux ratios (III/V=1.2 to 0.8, sample S3), in which the narrow and wide yellow arrows show the growth interruption interface and lattice polarity inversion boundary, respectively; in part (b), element distribution of the region that AlN grown with different III/V ratios, labeled as yellow dashed rectangular in part (a), with part (b) (i) depicting an ABF-STEM image and part (b) (ii) depicting the corresponding Al, Si, and N element maps; in part (c), integrated Al, Si, and N K-edge signal profiles along the yellow arrow labeled in part (b), showing a clear incorporation of Si at the growth interruption interface and the lattice polarity inversion boundary; in parts (d)-(g), high-resolution STEM images captured from the squares labeled in part (a), with part (d) depicting the growth interruption interface (red square), part (e) depicting the AISIN interlayer (green square), part (f) depicting the N-polar AlN below the AlSiN interlayer (orange square), and part (g) depicting Al-polar AlN above the AISIN interlayer (blue square); parts (d) (i)-(g) (i) are HAADF-STEM images, while parts (d) (ii)-(g) (ii) are the corresponding ABF-STEM images of the left part, and in which yellow arrows in part (d) indicate the growth interruption interface, and orange and blue dashed boxes in part (e) indicate the N-polar and Al-polar AlN regions, respectively. An AlN atomic model is overlaid in STEM images to visualize the stacking sequence. The pink and blue balls represent Al and N atoms, respectively.

Part (a) of FIG. 2 shows the cross-sectional ABF-STEM image of the AlN/Si heterostructures. In this case, two interlayers were observed in the AlN region: a thin interlayer (about 2 nm thick) induced by the growth interruption and a thick interlayer (about 10-20 nm thick) in the N-rich AlN region, indicated as narrow and wide yellow arrows, respectively. Due to the slightly larger growth rate of Al-rich AlN, the thin interlayer is disposed slightly above the middle of the entire AlN region, even though the growth duration periods are the same (e.g., 15 min) for the Al-rich conditions and the N-rich conditions.

To clarify the element distribution in the interlayer regions, energy-dispersive X-ray spectroscopy (EDS) was performed in the AlN region grown with different III/V ratios. Part (b) of FIG. 2 shows the EDS maps for Al, N and Si elements acquired from the yellow dashed rectangular region in part (a) of FIG. 2). The drop of Al signal within the growth interruption interface and thick interlayer regions is correlated with a rise of the Si signal within the same area, while there is no apparent change of N signal, suggesting Si atoms partially substituted Al atoms within the AlN lattice matrix. Considering these AlN films were unintentionally doped, the Al—Si eutectic is the sole source for Si atoms, i.e., the incorporation of Si atoms is due to the consumption of the Al—Si eutectic layer when AlN is grown with insufficient Al supply. The spatial distribution of Si matches well with the growth interruption interface and thick interlayer regions observed in the corresponding HAADF-STEM image (part (b) (i) of FIG. 2). Part (c) of FIG. 2 presents the integrated intensity profiles of Al, Si, and N K-edges recorded along the yellow arrow in part (b) (i) of FIG. 2, further confirming the incorporation of Si into AlN after switching the growth conditions from Al-rich to N-rich. Although the growth procedure was only interrupted 10 s for N₂ flow adjustment, the incorporation of Si is remarkable.

Although the growth procedure was only interrupted for 5 min for the Al flux adjustment in this example, the incorporation of Si is nonetheless very remarkable. Additionally, as shown in parts (b, c) of FIG. 2, there is a gap (about 5-10 nm), at which the Si signal dropped, between the growth interruption region and the thick interlayer. This is due to the initial N-rich condition was compensated by the Al-atoms from the Al—Si eutectic layer, while a real N-rich condition gradually formed with the consumption of Al atoms. Subsequently, the Si atoms were heavily incorporated into the AlN lattice, resulting in the rise of Si signal in the following AlN growth, i.e., the thick interlayer region.

Part (d) of FIG. 2 illustrates the HAADF-STEM and corresponding ABF-STEM images captured from the growth interruption interface. Due to the incorporation of Si from the Al—Si eutectic layer into the AlN lattice (part (c) of FIG. 2), the growth interruption region exhibits a dark contrast (part (d) (ii) of FIG. 2). However, both a wurtzite stacking sequence and a N-polar lattice were maintained well over this growth interruption region. In other words, the growth interruption induced thin interlayer is a Si-doped AlN layer. The lattice polarity thus remains unchanged at the growth interruption region, insofar as the number of Si atoms incorporated into the AlN lattice is sufficiently low to avoid a change in the lattice polarity.

Part (e) of FIG. 2 presents the HAADF-STEM image acquired from the thick interlayer region. Interestingly, N-polar stacking sequence (orange box), disordered stacking, and Al-polar stacking sequence (blue box) were observed sequentially from bottom to top, indicating that the lattice polarity was inverted from N-polar to Al-polar in this thick interlayer region. The stacking sequence in the transition region is similar to an AlON layer that was previously reported in AlN (see: Mohn et al., Phys. Rev. Appl. 5, 054004 (2016); Wang et al., Appl. Phys. Express 13, 095501 (2020); and Stolyarchuk et al., Sci. Rep. 8, 1 (2018)), which also induced lattice polarity inversion. As such, combining with the EDS results, this disordered lattice polarity transition region is defined as an AISIN interlayer, in which the wurtzite lattice is seriously distorted due to the incorporation Si atoms. Shown in parts (f, g) of FIG. 2, f, the lattice polarity for the AlN grown slightly below and above the transition region have well-stacked N-polar and Al-polar lattices, respectively. In this case, the thickness variation of the AlSiN interlayer may be primarily due to the non-uniform distribution of the Al—Si eutectic layer.

The disclosed methods and devices may include or incorporate an atomic stacking sequence based on the foregoing observations and analysis. A number of examples are described hereinbelow.

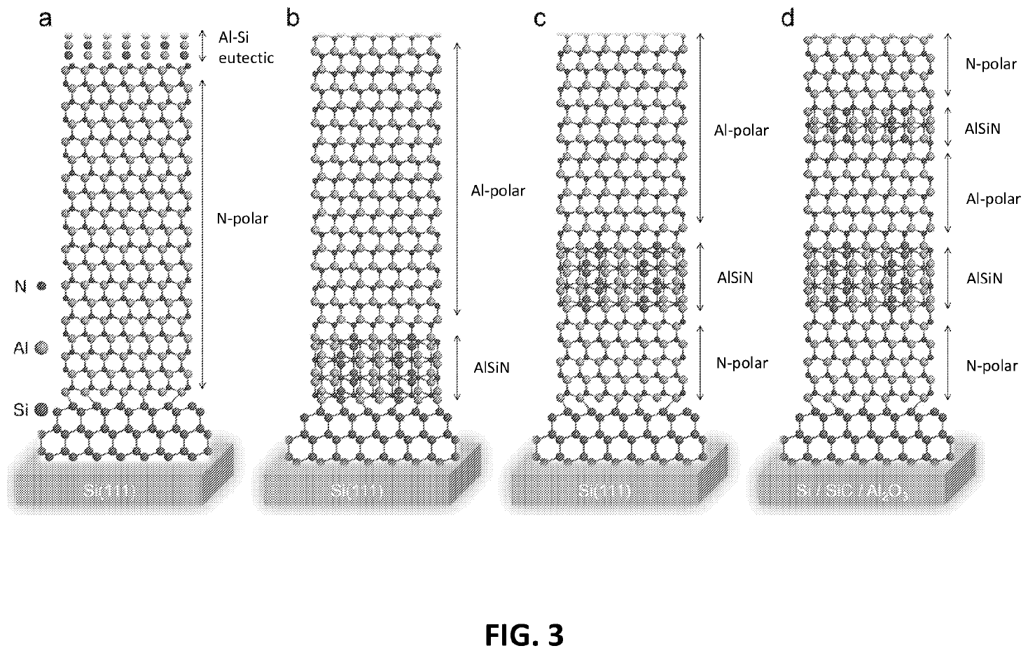

FIG. 3 schematically depicts examples of atomic stacking sequences of an AlN layer grown on a Si(111) substrate with and without an AISIN interlayer, with part (a) depicting a N-polar AlN layer grown on Si(111) without an AlSiN interlayer, part (b) depicting a heterostructure including an Al-polar AlN layer grown on Si(111) with an AISIN interlayer formed at the nucleation stage, part (c) depicting a heterostructure with the lattice polarity of an AlN layer grown on Si(111) switching from N-polar to Al-polar via the formation of an AlSiN interlayer during the growth, and part (d) depicting a heterostructure in which the lattice polarities of a number of AlN layers are alternately modulated by introducing a respective AISIN interlayer intentionally between adjacent AlN layers.

Comparing the experimental results with the atomic schematics, the lattice polarity control mechanism for the AlN layer grown on Si(111) can now be well explained as follows. In the example shown in part (a) of FIG. 3, without an AlSiN interlayer, the AlN layer has a N-polar lattice (as with sample S1). In the example shown in part (b) of FIG. 3, with an AISIN interlayer formed at the initial nucleation stage, the AlN layer possesses an Al-polar lattice (as with samples S2 and S4). In the example shown in part (c) of FIG. 3, with an AISIN interlayer formed during growth, the lattice polarity transforms or toggles from N-polar to Al-polar (as with sample S3). For sample S4, the Al—Si eutectic layer was consumed at the beginning, therefore, its lattice polarity did not toggle or change with the switching of III/V ratios during growth.

As exemplified by the samples and examples described above, the lattice polarity is determined by the AlSiN interlayer (e.g., the presence or absence thereof), and the lattice polarity can be precisely controlled by modulating the AlSiN interlayer (e.g., the presence or absence thereof). Moreover, the formation process of the AISIN interlayer can be adjusted by intentionally consuming the Al—Si eutectic layer, such as via N-plasma irradiation of the as-grown N-polar AlN/Si surface to form the AISIN interlayer in a short time. Furthermore, the lattice polarity of the AlN layer may be artificially modulated or otherwise controlled by intentionally introducing an AISIN interlayer (e.g., see part (d) of FIG. 3). In this manner, fully epitaxial growth of heterostructures or superlattices with layers of alternating lattice polarity is achievable.

Further example heterostructures with lattice polarity control were grown. In these cases, N-polar and Ga-polar GaN layers were grown on optimized N-polar and Al-polar AlN buffer layers by controlling the formation of an AISIN interlayer.

In one of the AlN—GaN heterostructure examples, an N-polar AlN layer is grown on a Si substrate. Based on the above analysis, the liquid phase Al—Si eutectic layer remains floating on the top surface during that growth (part (a) of FIG. 3). Consequently, during the growth interruption for the cooling down of the substrate, there is a significant chance of AlSiN interlayer formation, due to exposure in the active-nitrogen environment. In addition, during the growth of III-nitrides using MBE, the transitive property of the thermodynamic determines that the incorporation of cation species follows the order of Al, then Si, then Ga. Therefore, even without active nitrogen supply, the Al—Si eutectic layer will also participate in the following GaN growth, forming an AlGaSiN interlayer. The formation of these undesired interlayers results in Ga-polar domain formation in the subsequent N-polar GaN growth. In that way, some regions may be Ga-polar while others are N-polar.

In another one of the AlN—GaN heterostructure examples, the formation of the inverted domain is suppressed. In some cases, to suppress the formation of the inverted domain, an active-nitrogen-free in situ annealing procedure is used for N-polar GaN growth. A continuous growth procedure is divided into two steps: (i) switching off the N-plasma after the growth of an N-polar AlN layer, and ramping up the substrate temperature to 900° C. for 10 min in situ annealing; and (2) cooling down the substrate temperature to 700° C. and then striking the N-plasma and starting N-polar GaN growth. During the annealing procedure, without active nitrogen, most of the residual Al adatoms will desorb from the AlN surface. As a result, the formation of AlSiN interlayer in this growth interruption period is largely eliminated or avoided. Therefore, the effect of Al—Si eutectic layer and AlSiN interlayer can be suppressed significantly in the following growth. On the other hand, the desorption of Al adatoms is also useful for establishing a clean and sharp GaN/AlN interface by reducing interfacial Al incorporation. Moreover, the residual Si atoms on the surface will gradually incorporate into the N-polar GaN lattice during the subsequent growth, forming Si-doped GaN instead of a GaSiN interlayer as well as IDs, due to the slightly Ga-rich conditions employed for GaN film growth.

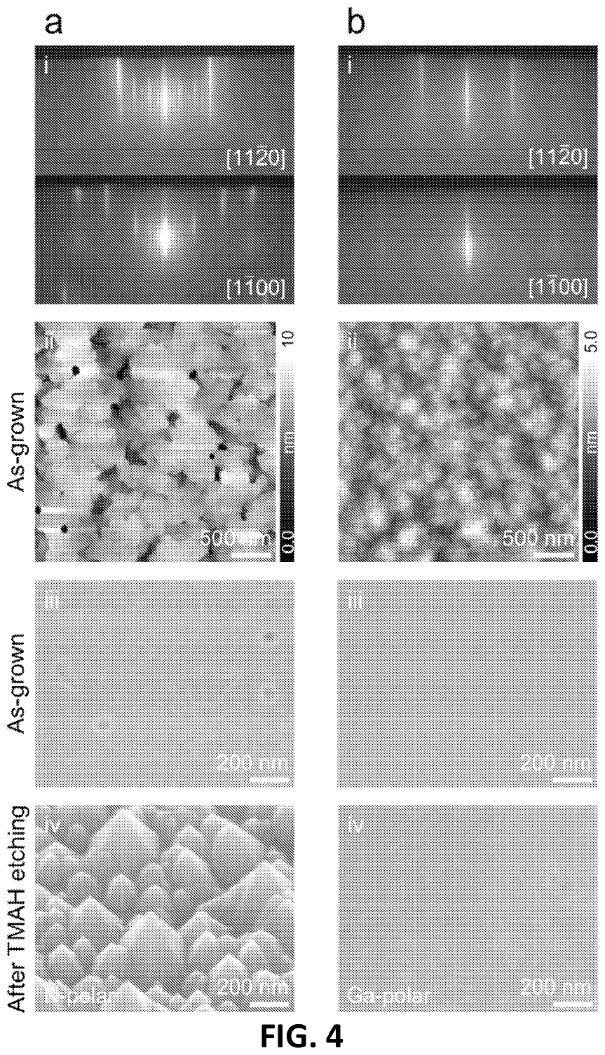

FIG. 4 depicts example GaN/AlN heterostructures grown on Si(111) substrates. Part (a) depicts an N-polar GaN/AlN heterostructure. Part (b) depicts a metal-polar GaN/AlN heterostructure. Panels (i), (ii), (iii), and (iv) of each part are the corresponding final RHEED patterns, AFM images, and SEM images (before and after wet chemical etching) of the GaN layer. The RMS roughness measurements for part (a) (ii) and part (b) (ii) are 1.40 nm and 0.39 nm, respectively.

Part (a) (i) of FIG. 4 shows the RHEED pattern (recorded at 200° C.) of the N-polar GaN layer grown with the active nitrogen-free in situ annealing procedure. The representative 3×3 reconstruction for N-polar GaN was clearly observed. Part (a) (ii) of FIG. 4 illustrates the surface morphology of the N-polar GaN layer with a corresponding RMS roughness of about 1.40 nm. After wet chemical etching, hexagonal pyramids were observed over the full wafer (see part (a) (iii, iv) of FIG. 4), suggesting N-polar lattice polarity for the GaN film or layer, which was further confirmed by the TEM analysis described below.

For Ga-polar GaN, the typical 1×1 reconstruction for metal-rich Ga-polar GaN is clearly observed in part (b) (i) of FIG. 4. The AFM image shows a smooth surface with a corresponding RMS roughness of 0.39 nm (see part (b) (ii) of FIG. 4). Shown in part (b) (iii) of FIG. 4, the surface is hardly changed with wet chemical etching, suggesting a pure Ga-polar GaN. In other cases, the in situ annealing technique may also be applied for Ga-polar GaN growth, but the N-plasma does not need to be switched off. The screw and edge dislocation densities are 2×10⁹ and 2×10¹⁰ cm⁻² for both N-polar and Ga-polar GaN grown on Si(111), respectively. The crystal quality is comparable with the GaN films directly grown on sapphire substrates by MBE.

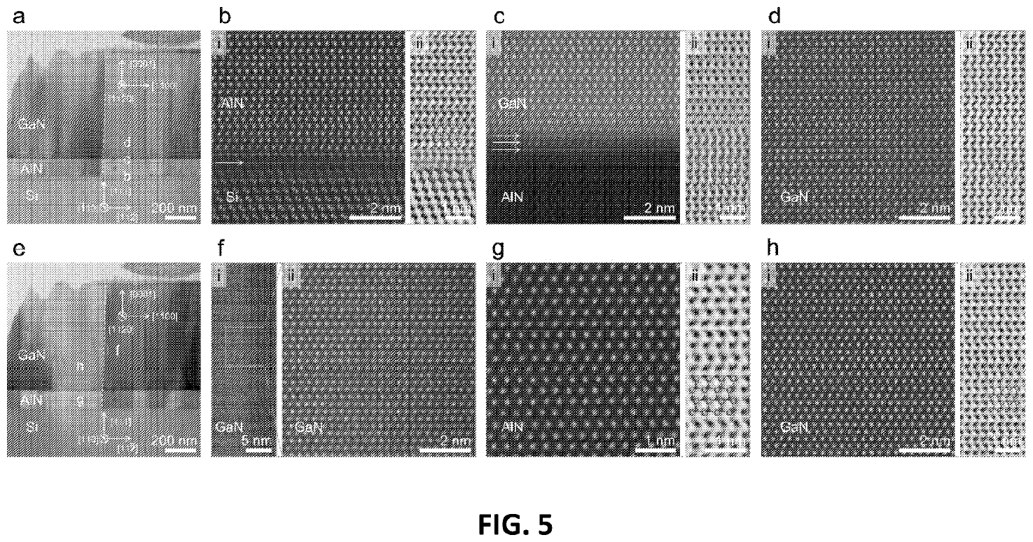

FIG. 5 is directed to the microstructural analysis of one example of a N-polar GaN/AlN/Si heterostructure. Part (a) depicts a cross-sectional ABF-STEM image of the GaN/AlN/Si heterostructures. Parts (b)-(d) depict high-resolution STEM images captured from the solid orange squares labeled in part (a). Specifically, part (b) shows the AlN/Si interface, part (c) shows the GaN/AlN interface, and part (d) shows the GaN epilayer. Part (e) depicts an ABF-STEM image of the same region shown in part (a), but the zone axis was gently adjusted. Part (f) depicts a HAADF-STEM image acquired from the domain boundary that labeled as green square in part (e). Parts (g) and (h) are high resolution STEM images captured from the dashed orange squares labeled in part (e), with part (g) showing the AlN buffer layer and part (h) showing the GaN epilayer. Parts (b) (i), (c) (i), (d) (i), (g) (i), and (h) (i) are HAADF-STEM images, while parts (b) (ii), (c) (ii), (d) (ii), (g) (ii), and (h) (ii) are the corresponding ABF-STEM images of the right part. The atomic models for Si, AlN, and GaN are overlaid in the ABF images to visualize the stacking sequence. The purple, pink, orange, and blue balls represent the Si, Al, Ga, and N atoms, respectively. The yellow dashed lines in parts (a) and (e) indicate one of the distinct domain boundaries, while the yellow arrows in parts (b) (i) and (c) (i) show the interface transition region.

With continued reference to FIG. 5, the microstructure of N-polar GaN grown with active-nitrogen-free in situ annealing was analyzed in detail using HAADF-STEM and ABF-STEM. Part (a) of FIG. 5 illustrates the overview ABF image of the N-polar GaN/AlN/Si heterostructures, showing clean and sharp AlN/Si and GaN/AlN interfaces. The atomic structure of three representative areas, labeled as solid orange squares in part (a) of FIG. 5, were characterized using high-resolution HAADF- and ABF-STEM images. Part (b) (i) of FIG. 5 shows the HADDF-STEM image acquired from the AlN/Si interface, in which an atomically sharp interface and highly ordered atomic stacking sequence are observed. The epitaxial relationship between AlN and Si is unambiguously confirmed as (0001̅)[112̅0]_{AlN}∥(111)[1̅10]. The transition between AlN and Si only happened in one monolayer, indicated by a yellow arrow in part (b) (i) of FIG. 5. The corresponding ABF-STEM image is shown in part (b) (ii) of FIG. 5, visualizing the atomic stacking sequence of Al and N atoms clearly. Therefore, the atomic structure can accordingly be configured, as overlaid in the ABF-STEM image. By comparing the experimental atomic structure with the schematic model, the lattice polarity of AlN is unambiguously confirmed as N-polar, which agrees well with the results shown in FIGS. 1 and 2. Also, no β-Si₃N₄ layer was observed at the AlN/Si interface, which is due to a replacement between the Si atoms and impinging Al atoms at the initial nucleation stage, resulting in a uniform release and aggregation of Si over the growth front.

Part (c) (i) of FIG. 5 presents the HADDF-STEM image recorded from the GaN/AlN interface, in which the wurtzite structure is well inherited from the underlying AlN buffer layer into a top GaN epilayer with a faint interface transition region (less than 3 MLs). Meanwhile, due to the heavy incorporation of Si atoms, the GaN lattice near the GaN/AlN interface was severely distorted (see part (c) (ii) of FIG. 5). However, as shown in part (d) of FIG. 5, a clear ABF image with sharp contrast of Ga and N atoms can be captured from the region slightly away from the GaN/AlN interface, confirming that the lattice polarity of the GaN layer is N-polar. This highly ordered atomic stacking sequence is maintained well up to the top surface.

The previously reported sharp IDBs, which result from the lattice polarity inverted domain formation, are not observed in both low- and high-magnification ABF-STEM images in our studies (see parts (a)-(d) of FIG. 5). However, as shown in part (a) of FIG. 5, the overview ABF-STEM image has some clear contrast fluctuations, which go through the entire heterostructures. One representative domain boundary formed between the bright and dark contrast is indicated as yellow dashed line in part (a) of FIG. 5. By gently adjusting the zone axis of the TEM slice (within 1°), the original contrast of ABF image was reversed, i.e., the bright (dark) contrast in part (a) of FIG. 5 changed into the dark (bright) contrast in part (e) of FIG. 5. Part (f) of FIG. 5 shows the atomic structure at the domain boundary. No clear atomic stacking disorder was observed, indicating a seamless stitching for the two domains with slight in-plane rotation. This slight misorientation mainly originates from the initial AlN nucleation on Si(111), in which the huge lattice mismatch (about 19%) introduces disordered alignment. The lattice polarity of AlN and GaN was further checked in the rotated domain. As shown in parts (g) and (h) of FIG. 5, the wurtzite structure and N-polar stacking sequence are well maintained in both the AlN buffer layer and the GaN epilayer of the rotated domain region. Several other boundaries observed in parts (a) and (e) of FIG. 5 were also checked, all of which show a N-polar lattice for both the GaN and AlN layers. These results suggest that the contrast fluctuation observed in parts (a) and (e) of FIG. 5 is only due to the non-uniform diffraction induced by the mild in-plane rotation rather than the inverted lattice polarity of two adjacent domains. Therefore, the N-polar GaN layer grown in conjunction with an active-nitrogen-free in situ annealing procedure is virtually free of IDs, which represents a major development in the epitaxy of N-polar GaN on Si. Such high quality N-polar GaN layers offer promising opportunities for next generation electronic and optoelectronic devices.

The lattice polarity control described herein may take advantage of a preferential order for incorporation of competing cation species into the growing crystal. For instance, during III-nitride growth, the order of incorporation of competing cation species is Al, then Si, then Ga, and then In. The manner in which the preferential order is utilized is described below in connection with an example in which AlN and GaN layers are grown.

During growth of the AlN layer on a Si substrate, an Al—Si eutectic layer forms on the growth surface. With sufficient Al supply, the Al—Si eutectic layer floats on top of the AlN growth front. However, with insufficient Al supply, both Al and Si from the Al—Si eutectic layer join the growth and form an AISIN layer. The AISIN layer destroys the wurtzite stacking sequence. The lattice polarity accordingly changes or switches, as described herein.

For N-polar AlN growth, sufficient Al flux is provided from the beginning to avoid the formation of AISIN, thereby maintaining pure (e.g., effectively pure) N-polarity. In this case, the Al—Si eutectic layer floats on the N-polar AlN surface.

The optimal growth temperatures for the AlN and GaN layer are different. In previous heterostructure growth procedures, after AlN growth, the growth temperature is ramped down for the subsequent GaN growth. During that process, no Al flux is supplied, but the N-plasma is still on, such that the growth chamber is under an active-nitrogen environment. In such cases, the floating Al—Si eutectic layer joins the growth, thereby forming some AISIN domains. As a result, there is a high possibility that some of the original N-polar lattice will be switched to Al-polar lattice, i.e., an Al-polar AlN domain formed during the growth temperature ramping down process. This scenario is avoided by the disclosed methods, including, for instance, the use of the active-nitrogen-free annealing described herein.

During the active-nitrogen-free annealing, the N-plasma source is completely switched off. As a result, Al and Si atoms do not join the growth during this process. With the temperature ramping up to the annealing temperature (rather than down to the GaN growth temperature), the Al atoms in the Al-eutectic layer start to desorb from the surface, and only Si atoms stay on the N-polar AlN surface. Subsequently, the temperature is ramped down to the GaN growth temperature, at which point the N-plasma source is restarted for growth of the GaN layer.

Because no growth happens during the annealing and growth temperature cooling down process, only Al atoms are desorbed from the surface. As a result, the original N-polar lattice of AlN will not be changed. Therefore, the following GaN growth can follow the N-polar AlN lattice.

As the GaN growth started, the residual Si atoms on the surface with Ga atoms together form another eutectic layer, e.g., a Ga—Si eutectic layer. However, due to the incorporation preference mentioned above, the Si atoms will gradually incorporate into the GaN lattice matrix during the subsequent growth, forming Si-doped GaN instead of a GaSiN interlayer as well as IDs, due to the slightly Ga-rich conditions employed for the GaN film growth.

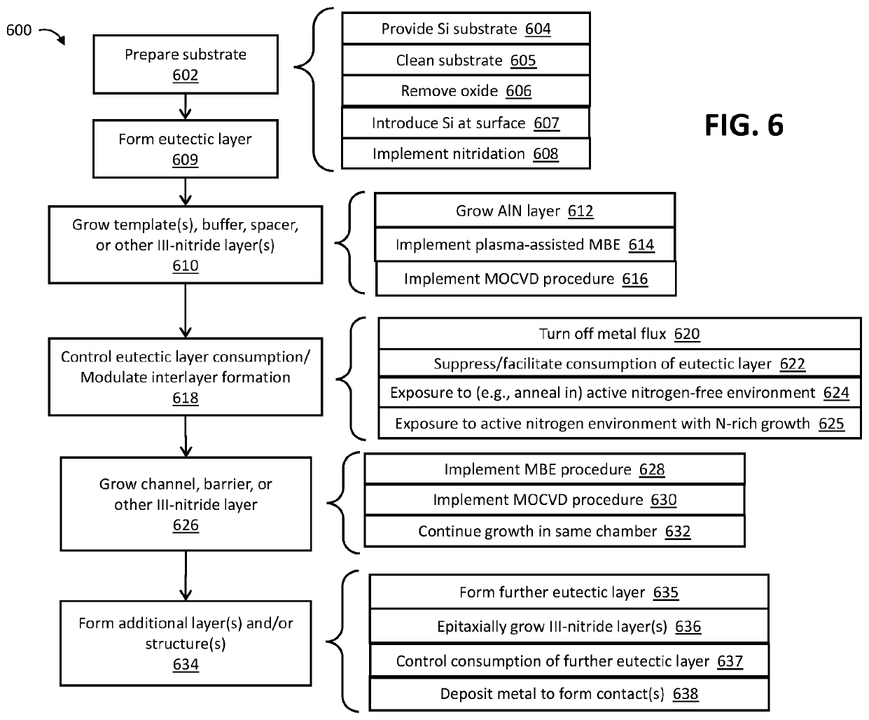

FIG. 6 depicts a method 600 of fabricating a heterostructure in which lattice polarity of respective layers of the heterostructure is controlled in accordance with one example. As described herein, the method 600 may be configured such that the heterostructure is free of lattice polarity inversions (e.g., inverted domains). Thus, in some cases, each of the heterostructures layers may be N-polar or, in other cases, metal-polar. In still other cases, the method 600 may be configured to intentionally introduce lattice polarity inversions, alternating between N-polar and metal-polar as desired. The heterostructure may form a device, or a part of a device, such as a HEMT device. The method 600 may be used to fabricate the heterostructure examples of described herein, as well as other heterostructures.

The method 600 may begin with an act 602 in which a substrate is prepared and/or otherwise provided. In some cases, the act 602 includes providing a silicon substrate (e.g., a Si(111) substrate) in an act 604. Alternative or additional materials may be used, including, for instance, bulk GaN, bulk AlN, or other semiconductor materials. Still other materials may be used, including, for instance, sapphire, silicon carbide, GaN/sapphire templates, and AlN/sapphire templates.

The substrate may be cleaned in an act 605. In some cases, a native or other oxide layer may be removed from a substrate surface in an act 606. Additional or alternative processing may be implemented in other cases, including, for instance, doping or deposition procedures. The substrate thus may or may not have a uniform composition. The substrate may be a uniform or composite structure.

In non-silicon substrate cases, the act 602 may include introduction (e.g., deposition) of Si atoms on the surface (e.g., the substrate surface) in an act 607. The introduced Si atoms allow the formation of a eutectic layer, such as a Si—Al eutectic layer, and eventually an intermediate layer doped with silicon, such as AISIN, as described herein.

The act 602 may include one or more further acts. For instance, in the example of FIG. 6, the act 602 includes an act 608 in which surface nitridation is implemented prior to the growth of semiconductor layers, such as AlN. Surface nitridation may be useful for avoiding the uncontrollable formation of AISIN layer at the initial nucleation stage. In addition, surface nitridation is helpful for improving surface uniformity.

In one example, the act 602 may include etching Si(111) wafers in buffer HF at room temperature for 1 min to remove the surface oxidation layer and further cleaned by deionized water prior to loading into the MBE system. The Si(111) substrates may then be baked and degassed at 200 and 600° C. in an MBE load-lock chamber and preparation chamber, respectively. In the growth chamber, the Si(111) substrate was heated up to 900° C. to completely decompose the native oxide.

In some cases, the method 600 includes an act 609 in which a eutectic layer is formed on a surface of the substrate. The act 609 may include the deposition of Si on the substrate surface. The act 609 is implemented before the growth of III-nitride layers of the heterostructure. The eutectic layer may be composed of, or otherwise include, a mixture of silicon and a group III metal, such as Al, as described herein. In some cases, atoms of the group III metal may be deposited concurrently with Si, in which case the eutectic layer may be formed before the growth is started. Otherwise, the eutectic layer is formed upon starting the growth due to the supply of Group III metal atoms in conjunction therewith. The act 609 may be implemented in cases in which a non-silicon substrate is used or in other cases in which the intentional formation of the eutectic layer is useful.

In an act 610, one or more semiconductor growth templates, buffer, spacer, or other layers are epitaxially grown in a growth chamber. The semiconductor layer(s) are thus formed on, or otherwise supported by, the substrate. In some cases, the semiconductor layer is in contact with the substrate, such as AlN/Si. In other cases, an intermediary layer is disposed between the semiconductor layer and the substrate, such as GaN grown on sapphire using an AlN layer as a buffer layer.

The semiconductor layer is composed of, or otherwise includes, a III-nitride material. In some cases, the semiconductor layer(s) are composed of, or otherwise include, AlN. Alternative or additional III-nitride semiconductor materials may be used, including, for instance, GaInN, AlGaN, AlInN, and InGaN. In the example of FIG. 6, an AlN layer is grown in an act 612.

In some cases, the semiconductor layer may act as a template for subsequent growth of one or more semiconductor layers. In some cases, the semiconductor layer is N-polar. Alternatively, the semiconductor layer is metal-polar.

In some cases, the acts 610, 612 may include growing the semiconductor layer in an epitaxial growth chamber in which subsequent acts (e.g., epitaxial growth procedure(s)) are implemented. As a result, the substrate may remain within, e.g., is not removed from, the epitaxial growth chamber between growth procedures.

The act 610 may include an act 614 in which the semiconductor layer is grown via implementation of a plasma-assisted MBE procedure. For instance, the layers grown in the act 614 (and/or other growth acts described herein) may use a Veeco GENxplor MBE system, equipped with a radio frequency (RF) nitrogen plasma source for active nitrogen supply (N′) and dual filament SUMO Knudsen cells for Al and Ga sources. In some cases, the plasma source may be operated with a N₂ flow rate of 0.3 sccm and an RF power of 350 W. The corresponding growth rate for GaN is about 240 nm/h under Ga-rich conditions. The Al beam equivalent pressure (BEP) was varied in the range of 7.2×10⁻⁸-1.1×10⁻⁷ Torr, while Ga BEP was maintained at 2.2×10⁻⁷ Torr. In some cases, for AlN layer growth, the substrate temperature was lowered to 800° C. GaN epilayer growth may be executed at 700° C. The growth parameters may vary in other cases. Alternative or additional procedures may be used. For instance, the semiconductor layer may be grown in an act 616 via implementation of a MOCVD procedure.

As described herein, the growth of the semiconductor layer in the act 610 results in the formation of a eutectic layer at the growth front of the semiconductor layer. For instance, the eutectic layer may be or include a liquid layer floating or otherwise disposed on top of the semiconductor layer. In some cases, the eutectic layer is composed of, or otherwise includes the Group III cation (or metal) species of the semiconductor layer and Si. For instance, in examples having a silicon substrate and an AlN semiconductor layer, the eutectic layer is composed of Al and Si. The composition of the eutectic layer may vary in accordance with the composition of the semiconductor layer.

Between the growth of the semiconductor layer in the act 610 and the growth of a subsequent semiconductor layer, the method 600 may include an act 618 in which an extent to which the eutectic layer floating or otherwise disposed on the semiconductor layer is consumed is controlled. Such control, in turn, controls a lattice polarity of the subsequent semiconductor layer. The act 618 may be implemented at or after the point at which the metal flux for the growth procedure of the act 610 is turned off in an act 620. The act 620 may also include an adjustment of the temperature of the substrate, an example of which is described below.

The act 618 may include an act 622 in which the consumption of the eutectic layer is either suppressed or facilitated. In the latter case, facilitating the consumption of the eutectic layer results in the formation of an intermediate layer (or interlayer). The intermediate layer may thus establish an interface between the semiconductor layer grown in the act 610 and a subsequently grown semiconductor layer. In contrast, suppressing the consumption of the eutectic layer accordingly avoids the formation of the intermediate layer.

As described herein, controlling the extent to which the eutectic layer is consumed controls the lattice polarity of the subsequently grown semiconductor layer based on whether the intermediate layer is formed from the eutectic material. The presence or absence of the intermediate layer controls the lattice polarity of the subsequently grown semiconductor layer relative to a lattice polarity of the previously grown semiconductor layer. For instance, the absence of the intermediate layer allows the lattice polarity to persist, or be maintained. Thus, if the previously grown semiconductor layer is N-polar, the subsequently grown semiconductor layer is N-polar. Conversely, if the previously grown semiconductor layer is metal-polar, the subsequently grown semiconductor layer is metal-polar.

In contrast, the presence of the intermediate layer switches or toggles the lattice polarity of the subsequently grown semiconductor layer from a lattice polarity of the previously grown semiconductor layer. Thus, if the previously grown semiconductor layer is N-polar, the subsequently grown semiconductor layer is metal-polar. Conversely, if the previously grown semiconductor layer is metal-polar, the subsequently grown semiconductor layer is N-polar. An unexpected aspect of such switching or toggling is that the lattice polarity of the subsequently grown layer does not depend on the growth conditions (e.g., metal-rich or N-rich conditions). After the Si—Al eutectic layer is consumed, either N-rich or metal-rich conditions may thus be used, and with no effect on the lattice polarity.

The intermediate layer may be composed of, or otherwise include, a crystalline material doped (e.g., heavily doped) with Si. In an example with an AlN semiconductor layer, the intermediate layer is composed of, or otherwise includes, AISIN. The composition of the intermediate layer may vary in accordance with the eutectic layer and/or the composition of the semiconductor layer.

The suppression of the consumption of the eutectic layer may include annealing the previously grown semiconductor layer in an active-nitrogen-free environment in an act 624. The annealing may be implemented without flux of a Group IIIA cation species of the previously grown III-nitride semiconductor material or of the subsequently grown III-nitride semiconductor material. In some cases (e.g., AlN examples), the temperature of the anneal may fall in a range from about 900° C. to about 1200° C. Other temperatures may be used, including, for instance, in cases involving other III-nitride materials. The temperature of the anneal may be set to a level sufficient to evaporate the Group IIIA metal atoms of the eutectic layer. Alternatively or additionally, the previously grown semiconductor layer is exposed to an active-nitrogen-free environment.

Facilitating consumption of the eutectic layer may include exposing the eutectic layer to an active nitrogen environment in connection with subsequent N-rich growth in an act 625. For instance, the eutectic layer may exposed to a nitrogen-rich environment in preparation for the growth of a subsequent semiconductor layer. Such subsequent growth may then be implemented in a nitrogen-rich environment.

The method 600 includes an act 626 in which another semiconductor layer of the heterostructure is grown. As a result, the semiconductor layer grown in the act 626 is supported by the semiconductor layer grown in the act 610. The semiconductor layer grown in the act 626 is composed of, or otherwise includes, a III-nitride semiconductor material. The III-nitride semiconductor material may be the same as, or differ from, the material grown in the act 610. In some cases, the III-nitride semiconductor material is composed of, or otherwise includes, GaN, but alternative or additional III-nitride semiconductor materials may be used, including, for instance, AlN and alloys of GaN and AlN. The growth conditions may be set such that the semiconductor layers may be lattice matched or mismatched, as described herein.

The act 626 may include an act 628 in which the semiconductor layer is grown via implementation of an MBE procedure. Alternatively, a MOCVD procedure is implemented in an act 630. In either case, the growth may be continued in an act 632 in which in the same chamber used in the act 610 is used to grow the supporting semiconductor layer.

In some cases, one or both of the acts 610 and 626 are implemented in a metal-rich environment, e.g., under metal-rich conditions such as Al-rich or Ga-rich conditions. For instance, metal-rich conditions may be used when growing an N-polar AlN buffer or other layer, and/or any subsequent N-polar III-nitride layers, such as N-polar GaN layers. Alternatively, one or both of the acts 610 and 626 are implemented under N-rich conditions. For instance, N-rich conditions may be used when growing a metal-polar AlN buffer or other layer, and/or any subsequent metal-polar III-nitride layers, such as metal-polar GaN layers. In other cases, the nature of the growth environment may vary between respective layers of the heterostructure.

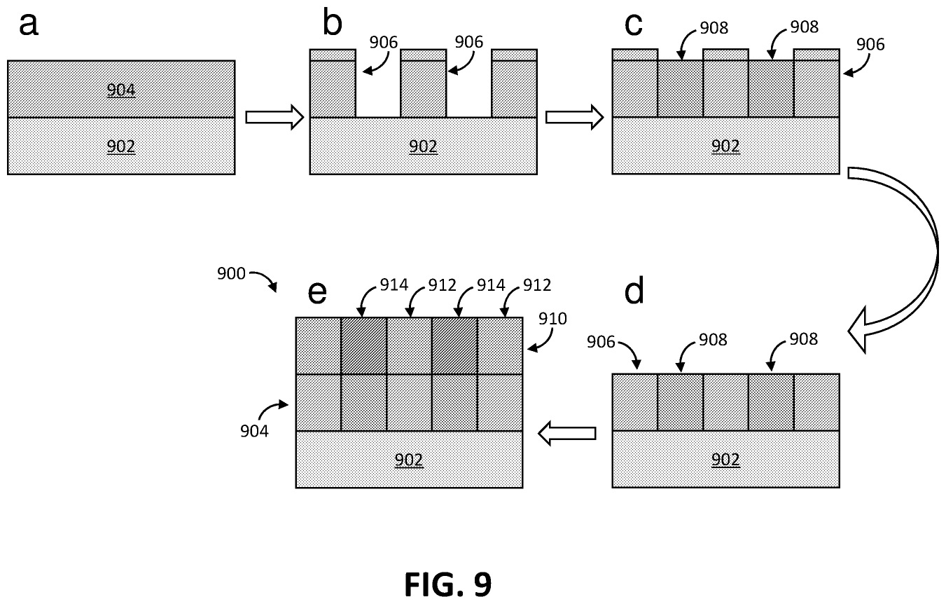

One or both of the acts 610 and 626 may include a photolithographic or other patterning procedure for lateral lattice polarity control. The patterning procedure may include the use of one or more masks to selectively grow, deposit, or otherwise form portions of the heterostructure. In this manner, a respective layer of the heterostructure may include any number of sections, segments, or other portions of differing lattice polarity and/or other characteristics, such as composition. An example of such patterning procedures is set forth below in connection with FIG. 9.

The method 600 may include an act 634 in which one or more additional layers of the heterostructure or other structures are formed. In some cases, the act 634 includes forming another eutectic layer in an act 635, and growing one or more III-nitride layers in an act 636. In some cases, the act 635 includes depositing silicon atoms on the surface of the topmost semiconductor layer. The act 635 may also include depositing Group III atoms (e.g., Al atoms), In this case, the eutectic layer is formed prior to the next layer being started in the act 636. Otherwise, the eutectic layer is formed once the growth of the next layer is started in the act 636. Consumption of the further eutectic layer may then be controlled in an act 637 to control the lattice polarity of the III-nitride layer grown in the act 636. In these ways, for example, a channel layer and/or cap layer of a HEMT device may be grown. The growth of the channel layer, cap layer, and/or other layers may or may not be supported by the lattice polarity control techniques described herein. These procedures of the act 634 may be repeated any number of times to form any number of semiconductor layers of the heterostructure.

The act 634 may also include an act 638 in which one or more metal layers are deposited and patterned to form one or more contacts or electrodes. For example, metal may be deposited to form source, drain, and gate electrodes of an HEMT device.

The method 600 may include fewer, alternative, or additional acts. For example, the method 600 may include the implementation of one or more doping procedures for one or more of the semiconductor layers described herein. Such doping may be useful in connection with charge carrier confinement and/or other purposes. The method 600 may also include any number of additional acts directed to the growth or other formation of additional semiconductor layers, such as cap layers.

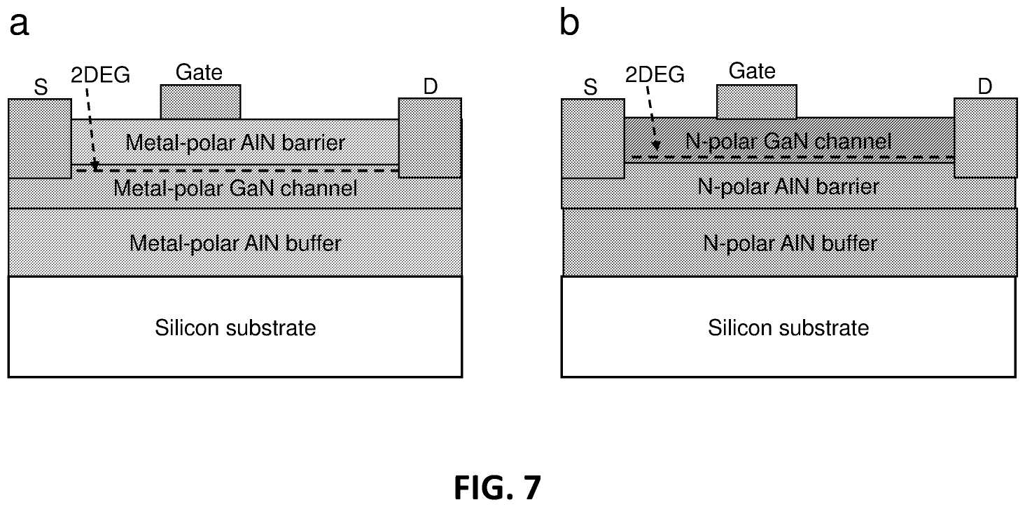

FIG. 7 depicts devices having heterostructures in accordance with two examples. The devices may be fabricated via the method 600 of FIG. 6 and/or another method. In these two examples, the devices are configured either as a metal-polar HEMT device (part A) or a nitrogen-polar HEMT device (part B). In other cases, the device is configured as a non-electronic device.

The device includes a substrate and a semiconductor heterostructure supported by the substrate. The substrate may be composed of, or otherwise include, silicon, but alternative or additional materials may be used, including for instance, SiC. In the examples of FIG. 7, the heterostructure is in contact with the substrate. In other cases, one or more layers are disposed between the substrate and the heterostructure.

The device includes a buffer or other semiconductor layer of the heterostructure. The buffer layer is supported by the substrate. In the examples of FIG. 7, the buffer layer is in contact with the substrate. The buffer layer is composed of, or otherwise includes, a first III-nitride semiconductor material. In these example cases, the first III-nitride semiconductor material is AlN, but other III-nitride semiconductor materials may be used, including, for instance, GaN and alloys of AlN and GaN. The buffer layer may be doped, unintentionally doped, or un-doped.

In some cases, the device further includes a spacer layer. The spacer layer may be in contact with the buffer layer. The spacer layer may be composed of, or otherwise include, a III-nitride semiconductor material, such as AlN, but other materials may be used.

The heterostructures of each of the devices includes a barrier or other semiconductor layer. In the example of FIG. 7, part (a), the barrier layer is supported by the buffer layer. In the example of FIG. 7, part (b), the barrier layer is in contact with the buffer layer. The barrier layer is composed of, or otherwise includes, a III-nitride semiconductor material. The III-nitride semiconductor material may differ from the first III-nitride semiconductor material.

The buffer, barrier, and other layers may be lattice matched or lattice mis-matched.

In the HEMT examples of FIG. 7, the device also includes a channel layer. In the metal-polar HEMT structure (part a), the channel supports the barrier layer. In the nitrogen-polar HEMT structure (part b), the channel is supported by the barrier layer. The channel layer may be in contact with the barrier layer. In other cases, one or more semiconductor layers may be disposed between the channel and barrier layers. The channel layer is composed of, or otherwise includes, a compound semiconductor material, such as a Ill-nitride semiconductor material, e.g., GaN, AlGaN, InGaN, or InN.

The lattice polarity of the respective semiconductor layers of the heterostructures may vary in other cases.

The heterostructures may include one or more further semiconductor layers. For instance, the heterostructure may include a semiconductor layer disposed between the buffer and barrier layers. The further semiconductor layer may be composed of, or otherwise include, a third III-nitride semiconductor material (e.g., AlGaN) differing from the first III-nitride semiconductor material. The further semiconductor layer may be metal-polar or N-polar, insofar as the lattice polarity of the layers of the heterostructure may follow the polarity of the initial buffer layer, as described herein.

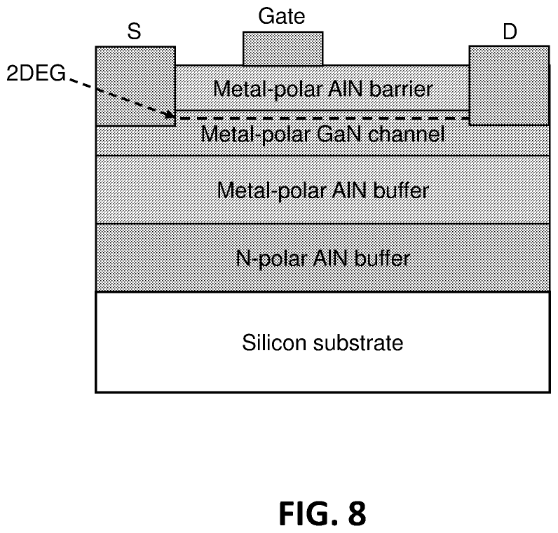

FIG. 8 depicts a HEMT device having a heterostructure with alternating lattice polarity in accordance with another example. The device may be fabricated via the method 600 of FIG. 6 and/or another method. As with the above-described examples, the device includes a substrate that supports a number of III-nitride semiconductor layers of the heterostructure. At least two adjacent semiconductor layers have alternating lattice polarity. In this example, a first AlN buffer layer in contact with the substrate is N-polar, and a second AlN buffer layer adjacent to the first AlN buffer layer is metal-polar. A GaN channel layer and an AlN barrier layer may also be metal-polar. The material compositions, lattice polarities, and other characteristics of the layers of the heterostructure may vary from the example shown. For instance, the second buffer layer may be metal-polar, and the barrier and channel layers may be N-polar.

FIG. 9 depicts a GaN/AlN/Si heterostructure 900 having controlled lateral lattice polarity in accordance with one example. The heterostructure 900 may be fabricated via the method 600 of FIG. 6 and/or another method. As with the above-described examples, the heterostructure 900 includes a substrate 902 that supports a number of III-nitride semiconductor layers of the heterostructure 900. In this example, the semiconductor layers have alternating lateral lattice polarity.

An AlN buffer layer 904 in contact with the substrate 902 is grown in part a of FIG. 9. In this example, the AlN buffer layer 904 is metal-polar. The AlN buffer layer 904 is selectively etched to expose the substrate surface, leaving a set of metal-polar AlN sections 906, as shown in part b of FIG. 9. A set of N-polar AlN buffer sections 908 is selectively deposited or grown in the etched regions, as shown in part c of FIG. 9. A mask is then removed for subsequent structure growth, as shown in part d of FIG. 9. In this example, a GaN layer 910 is grown on the sections 906, 908 of the AlN buffer layer 904. The GaN layer 910 has alternately switched lateral lattice polarity, insofar as the GaN layer will inherit the lattice polarity of the AlN buffer layer, i.e., the GaN layer includes metal-polar sections 912 and N-polar sections 914 arranged to exhibit the alternatively switched lateral lattice polarity, as shown in part e of FIG. 9. The material compositions, lattice polarities, and other characteristics of the layers of the heterostructure may vary from the example shown. For instance, the buffer layer may be N-polar first, with the second buffer layer then being metal-polar.

The number, arrangement, and other characteristics of the sections may vary. For instance, a set of sections may include any number of sections greater than or equal to one. In some cases, the sections are disposed in a periodic arrangement. For instance, the sections of one set may periodically alternate with the sections of the other set.

Described above are examples of methods and devices involving the growth of both N-polar and metal-polar III-nitride heterostructures (e.g., GaN/AlN heterostructures on Si(111) substrates). Detailed microstructure analyses of example heterostructures confirmed that the lattice polarity of AlN on Si highly depends on the presence or absence of an AlSiN interlayer. N-polarity and Al-polarity can be realized by suppressing and promoting AISIN interlayer formation, respectively, during the growth of AlN. Using active nitrogen-free in situ annealing, the growth of pure N-polar (or metal-polar) GaN/AlN on Si(111) has been achieved. STEM analyses of examples show clear, clean, and atomically sharp GaN/AlN/Si interfaces, and further reveal a highly ordered stacking sequence for a pure N-polar GaN/AlN/Si heterostructure, which has been one of the main challenges for III-nitride heterostructures grown on Si. The lattice polarity controlled epitaxy of nitride heterostructures on Si(111) (e.g., N-polar structures), will be useful for next-generation high-frequency power electronic devices, as well as high-efficiency micro-/nano-optoelectronic devices, and will further enable seamless integration with the mature Si-based device technology.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A method of fabricating a heterostructure, the method comprising:
growing epitaxially, in a growth chamber, a first semiconductor layer of the heterostructure, the first semiconductor layer comprising a first III-nitride semiconductor material, the first semiconductor layer being supported by a substrate;
after growing the first semiconductor layer, growing epitaxially, in the growth chamber, a second semiconductor layer of the heterostructure such that the second semiconductor layer is supported by the first semiconductor layer, the second semiconductor layer comprising a second III-nitride semiconductor material; and
between growing the first semiconductor layer and growing the second semiconductor layer, controlling an extent to which a eutectic layer disposed on the first semiconductor layer is consumed to control a lattice polarity of the second semiconductor layer.

2. The method of claim 1, wherein controlling the extent to which the eutectic layer is consumed controls the lattice polarity of the second semiconductor layer based on whether an intermediate layer is formed from the eutectic material between the first and second semiconductor layers.

3. The method of claim 2, wherein presence of the intermediate layer between the first and second semiconductor layers toggles the lattice polarity of the second semiconductor layer from a lattice polarity of the first semiconductor layer.

4. The method of claim 2, wherein absence of the intermediate layer between the first and second semiconductor layers allows a lattice polarity of the first semiconductor layer to persist in the second semiconductor layer.

5. The method of claim 1, wherein the eutectic layer comprises silicon and a Group III cation species of the first III-nitride semiconductor material.

6. The method of claim 1, wherein:
consumption of the eutectic layer forms an intermediate layer between the first and second semiconductor layers;
the intermediate layer is doped with silicon; and
the intermediate layer establishes an interface between the first and second semiconductor layers.

7. The method of claim 1, wherein controlling the extent to which the eutectic layer is consumed comprises suppressing consumption of the eutectic layer.

8. The method of claim 7, wherein suppressing the consumption comprises annealing the first semiconductor layer in an active-nitrogen-free environment.

9. The method of claim 8, wherein annealing the first semiconductor layer is implemented without flux of a Group III cation species.

10. The method of claim 7, wherein the first and second semiconductor layers are nitrogen polar.

11. The method of claim 1, wherein controlling the extent to which the eutectic layer is consumed comprises facilitating consumption of the eutectic layer.

12. The method of claim 11, wherein facilitating consumption of the eutectic layer comprises:
exposing the eutectic layer to an active nitrogen environment; and
growing the second semiconductor layer in a nitrogen-rich environment.

13. The method of claim 11, wherein one of the first and second semiconductor layers is nitrogen polar, and the other of the first and second semiconductor layers is metal polar.

14. The method of claim 1, further comprising forming the eutectic layer on a surface of the substrate before growing the first semiconductor layer.

15. The method of claim 1, further comprising:
forming a further eutectic layer on a surface of the second semiconductor layer;
growing epitaxially, in the growth chamber, a III-nitride semiconductor layer of the heterostructure such that the III-nitride semiconductor layer is supported by the second semiconductor layer; and
controlling an extent to which the further eutectic layer disposed on the second semiconductor layer is consumed to control a lattice polarity of the III-nitride semiconductor layer supported by the second semiconductor layer.

16. The method of claim 1, wherein the first semiconductor material is aluminum nitride (AlN).

17. The method of claim 1, wherein the second semiconductor material is gallium nitride (GaN).

18. The method of claim 1, wherein the substrate comprises silicon such that the eutectic layer comprises silicon.

19. The method of claim 1, wherein growing epitaxially the first semiconductor layer is implemented in a metal-rich environment.

20. The method of claim 1, wherein growing epitaxially the second semiconductor layer is implemented in a metal-rich environment.

21. The method of claim 1, wherein growing the second semiconductor layer is implemented without removal of the substrate from the growth chamber after growth of the first semiconductor layer.

22. A method of fabricating a heterostructure, the method comprising:
growing epitaxially a first semiconductor layer of the heterostructure, the first semiconductor layer comprising a first III-nitride semiconductor material, the first semiconductor layer being supported by a substrate;
growing epitaxially a second semiconductor layer of the heterostructure such that the second semiconductor layer is supported by the first semiconductor layer, the second semiconductor layer comprising a second III-nitride semiconductor material; and
between growing the first semiconductor layer and growing the second semiconductor layer, annealing the first semiconductor layer in an active nitrogen-free environment to evaporate Group IIIA metal atoms of a eutectic layer disposed on the first semiconductor layer to maintain a lattice polarity of the first semiconductor layer in the second semiconductor layer.

23. A method of fabricating a heterostructure, the method comprising:
growing epitaxially a first semiconductor layer of the heterostructure, the first semiconductor layer comprising a first III-nitride semiconductor material, the first semiconductor layer being supported by a substrate;
growing epitaxially a second semiconductor layer of the heterostructure such that the second semiconductor layer is supported by the first semiconductor layer, the second semiconductor layer comprising a second III-nitride semiconductor material; and
between growing the first semiconductor layer and growing the second semiconductor layer, exposing an incidental eutectic coating on the first semiconductor layer to an active nitrogen environment, the incidental eutectic coating comprising silicon and a cation species of the first III-nitride semiconductor material;
wherein growing the second semiconductor layer is implemented in a nitrogen-rich environment such that exposing the incidental eutectic coating forms an intermediate layer at an interface between the first and second semiconductor layers from the incidental eutectic coating such that a lattice polarity of the second semiconductor layer is toggled relative to the first semiconductor layer.

24. A device comprising:
a substrate; and
a semiconductor heterostructure supported by the substrate, the semiconductor heterostructure comprising:
a first semiconductor layer supported by the substrate and comprising a first III-nitride semiconductor material; and
a second semiconductor layer supported by, and in contact with, the first semiconductor layer and comprising a second III-nitride semiconductor material differing from the first III-nitride semiconductor material;
wherein the first and second semiconductor layers are nitrogen polar.

25. The device of claim 24, wherein:
the first semiconductor material is aluminum nitride (AlN);
the second semiconductor material is gallium nitride (GaN); and
the substrate comprises silicon.

26. The device of claim 24, wherein:
the first semiconductor layer is configured as a buffer layer of a transistor device; and
the second semiconductor layer is configured as a channel layer of the transistor device.

27. The device of claim 26, wherein the semiconductor heterostructure further comprises a barrier layer supported by the buffer layer and comprising a compound semiconductor material, wherein the barrier layer is nitrogen polar.

28. A device comprising:
a substrate; and
a semiconductor heterostructure supported by the substrate;
wherein:
the semiconductor heterostructure comprises a plurality of III-nitride semiconductor layers supported by the substrate;
the semiconductor heterostructure further comprises a plurality of intermediate layers, each intermediate layer of the plurality of intermediate layers being disposed between a respective pair of adjacent III-nitride semiconductor layers of the plurality of III-nitride semiconductor layers;
each intermediate layer of the plurality of intermediate layers comprises silicon; and
the adjacent III-nitride semiconductor layers of each pair of adjacent III-nitride semiconductor layers of the plurality of III-nitride semiconductor layers have different lattice polarities.

29. The device of claim 28, wherein:
each intermediate layer of the plurality of intermediate layers comprises a doped crystalline material; and
the doped crystalline layer is doped with silicon.

30. The device of claim 28, wherein each intermediate layer of the plurality of intermediate layers comprises AlSiN.

31. The device of claim 28, wherein each semiconductor layer the plurality of semiconductor layers is composed of a same III-nitride semiconductor material.

32. The device of claim 28, wherein at least two of the plurality of semiconductor layers are composed of different III-nitride semiconductor materials.

33. A device comprising:
a substrate; and
a semiconductor heterostructure supported by the substrate;
wherein:
the semiconductor heterostructure comprises a plurality of III-nitride semiconductor layers supported by the substrate; and
a first III-nitride semiconductor layer of the plurality of III-nitride semiconductor layers comprises:
a first section having a first lattice polarity; and
a second section laterally adjacent to the first section and having a second lattice polarity differing from the first lattice polarity.

34. The device of claim 33, wherein:
the plurality of III-nitride semiconductor layers comprises a second III-nitride semiconductor layer supported by the first III-nitride semiconductor layer;
the first and second III-nitride semiconductor layers have different compositions;
the second III-nitride semiconductor layer comprises first and second sections supported by the first and second sections of the first III-nitride semiconductor layer, respectively, and having the first and second lattice polarities, respectively.

35. The device of claim 33, wherein:
the first III-nitride semiconductor layer comprises a set of N-polar sections and a set of metal-polar sections; and
the set of N-polar sections and the set of metal-polar sections are disposed in a periodic, alternating arrangement.
